(19) United States
(12) Patent Application Publication
(10) Pub. No.: US 2014/0085601 A1
(43) Pub. Date: Mar. 27, 2014

(54) CONTACT LENS HAVING A CHIP INTEGRATED INTO A POLYMER SUBSTRATE AND METHOD OF MANUFACTURE

(71) Applicant: GOOGLE INC., (US)

(72) Inventor: James Etzkorn, Mountain View, CA (US)

(21) Appl. No.: 13/626,589

(22) Filed: Sep. 25, 2012

(51) Int. Cl. G02C 7/04; H01L 21/50; H01L 21/56

(52) U.S. Cl. 351/159.03; 438/127; 438/106; 257/E21.502; 257/E21.499

(57) ABSTRACT

Contact lenses and methods of manufacture are provided. In one aspect, a method includes: positioning components in predefined locations on a first surface; applying pressure on the components employing a second surface; providing molten material between the first surface and the second surface and around the components; embedding the components in a substrate by cooling the molten material and causing the molten material to harden, the substrate being a substantially solid form of molten material; and removing the first surface and the second surface after embedding the components in the substrate. The method can also include: providing, on or within a contact lens, one of the components and the substrate into which the component is embedded. The first surface can include molds sized to receive and maintain the components at the predefined locations. The first surface and/or the second surface can be pre-treated with a non-stick coating such as Polytetrafluoroethylene.

### TECHNICAL FIELD

This disclosure generally relates to a contact lens having a chip integrated into a polymer substrate and method of manufacture.

### BRIEF DESCRIPTION OF THE DRAWINGS

FIGS. 1A and 1B are illustrations of diagrams of top and side views of an exemplary non-limiting contact lens having a chip integrated into a polymer substrate in accordance with aspects described herein.

FIGS. 1C and 1D are illustrations of top and side views of a first surface having molds configured to receive and maintain chips in predefined locations in accordance with aspects described herein.

FIGS. 1E and 1F are illustrations of side and top views of an exemplary non-limiting plurality of chips positioned on a first surface in accordance with aspects described herein.

FIG. 1G is an illustration of a side view of an exemplary non-limiting plurality of chips positioned between a first surface and a second surface in accordance with aspects described herein.

FIG. 1H is an illustration of a side view of an exemplary non-limiting plurality of chips positioned between a first surface and a second surface and having molten polymer disposed around the plurality of chips in accordance with aspects described herein.

FIG. 1I is an illustration of a side view of an exemplary non-limiting substrate positioned between a first surface and a second surface and having a plurality of chips completely embedded in the substrate in accordance with aspects described herein.

FIGS. 1J and 1K are illustrations of top and side views of exemplary non-limiting substrate on the first surface and having chips embedded in the substrate in accordance with aspects described herein.

FIGS. 1L and 1M are illustrations of top and side views of a polymer substrate having an integrated chip in accordance with aspects described herein.

FIGS. 2, 3, 4 and 5 are illustrations of exemplary flow charts of methods of manufacturing a contact lens having a chip integrated into a polymer substrate in accordance with aspects described herein.

FIG. 6 is an illustration of a schematic diagram of an exemplary networked or distributed computing environment with which one or more aspects described herein can be associated.

FIG. 7 is an illustration of a schematic diagram of an exemplary computing environment with which one or more aspects described herein can be associated.

### DETAILED DESCRIPTION

Various aspects are now described with reference to the drawings, wherein like reference numerals are used to refer to like elements throughout. In the following description, for purposes of explanation, numerous specific details are set forth in order to provide a more thorough understanding of one or more aspects. It is evident, however, that such aspects can be practiced without these specific details. In other instances, structures and devices are shown in block diagram form in order to facilitate describing one or more aspects.

Functionality of active contact lenses, cost and performance efficiency of devices on the contact lens are of utmost importance. To facilitate functionality while maintaining low cost and superior performance, chips (or, integrated circuits) can be included in the contact lens. Chips are electronic circuits typically fabricated by lithography or patterned diffusion of trace elements into a substrate of semiconductor material.

Semiconductor device fabrication is a multi-step process used to create chips. Fabrication can include lithographic and chemical processing (e.g., etching) during which electronic circuits are created on a wafer/substrate of semiconducting material. Silicon is typically employed for substrates, although other materials can be used for more specialized applications.

In typical device fabrication, chips are built on top of a single substrate. The substrate is generally formed of mono-crystalline cylindrical ingots up to 300 millimeters (mm) in diameter. These ingots are sliced into wafers about 0.75 mm thick and polished to obtain a regular and flat surface.

To produce a chip, deposition, removal, patterning and/or modification of electrical properties are usually involved. A first step, deposition, is a process by which material is grown, applied and/or otherwise provided on the substrate. Chemical vapor deposition, physical vapor deposition, electrochemical deposition, molecular beam epitaxy and/or atomic layer deposition can be employed for the deposition process.

Next, the removal process involves removing material from the substrate via wet etching or dry etching processes and/or via chemical mechanical planarization. Next, the patterning process involves shaping or altering the existing shape of the materials deposited on the substrate. For example, lithography can be employed for patterning. In conventional lithography, the substrate can be coated with a photo resist. Selected portions of the substrate can then be exposed to short wavelength light to wash away the exposed portions. The photo resist is then removed via plasma ashing. Finally, modification of electrical properties includes doping processes (e.g., transistor sources and/or drains) and activating the implanted dopants.

Substrates are typically reduced in thickness before the substrate/wafer is scored and broken into individual die. Numerous types of materials can be employed for substrates. Thermoplastics are polymers that become moldable above a particular temperature and return to a solid state upon cooling. Most thermoplastics have a high molecular weight with chains that associate through intermolecular forces. As such, thermoplastics can be remolded.

A thermoplastic changes without an associated phase change at temperatures above its glass transition temperature and below its melting point. Within this temperature range, thermoplastics are typically rubbery due to alternating rigid crystalline and elastic amorphous regions. Common thermoplastics include, but are not limited to, Polytetrafluoroethylene (PTFE) (also referred to as TEFLON®) and Polyethylene terephthalate (PET).

Wire bonding is a method of welding a wire between a chip and mechanical carrier using heat, pressure and ultrasonic energy. In some cases, wire bonding is employed for making interconnections between a chip and a printed circuit board. Bond wires are typically aluminum, gold or copper, with copper being the preferred wire material because the wire diameter for copper can be smaller than that for gold and yet the performance for the copper wires is the same or similar to the performance for gold wires. Further, copper is preferred over aluminum in cases in which high current capacity is needed or in cases of complex system geometries.

The wire bonding can be used to attach a chip to a mechanical carrier. The wires lead to pins on the outside of the mechanical carriers, which can be attached to other circuitry in the overall system in which the chip is located.

Near the chip edges, the chips are typically individually patterned with metal pads that provide connections to the mechanical carriers. While it is advantageous to include chips in contact lenses, the chip is typically attached to the top of the surface of the substrate. The metal pad, then can lend additional height as the metal pad can be placed on top of the chip. The final product is a thick stack that includes the substrate, metal pad and chip. Unfortunately, the stack can be too large to be embedded into a contact lens.

As such, in aspects described herein, a contact lens is fabricated having a chip integrated into a polymer substrate to reduce size of the stack. In some aspects, surfaces of the chip and substrate are continuous without gaps and height of the chip-substrate combination is advantageously reduced (relative to aspects wherein the chip is fabricated on the substrate and the metal pads also contribute further height to the stack). The chip-substrate combination can have a maximum height equal to height of the chip and the one or more connection pads on the chip in various aspects. These aspects advantageously reduce height of the stack and minimize area of the chip-substrate combination in the contact lens.

In one aspect, a method of manufacture includes: positioning one or more components in predefined locations on a first surface, wherein the one or more components are adapted to be embedded in a contact lens; applying pressure on the one or more components employing a second surface; providing a molten material between the first surface and the second surface and around the one or more components; embedding the one or more components in a substrate by cooling the molten material and causing the molten material to harden, the substrate being a substantially solid form of the molten material; and removing the first surface and the second surface after embedding the one or more components in the substrate.

In one aspect, a contact lens includes: a chip embedded in a substrate such that the chip and the substrate form a continuous surface, wherein the chip is embedded in the substrate based, at least, on a hardening of molten liquid provided around the chip; and a contact lens polymer encapsulating the chip and substrate.

In one aspect, a method includes: integrating a component into a polymer substrate. In some aspects, integrating includes: providing the component on a first surface, the first surface being pre-treated with a non-stick coating and the component having a bottom surface proximate to the first surface; applying pressure to a top surface of the component using a second surface, wherein the top surface of the component is opposite the bottom surface of the component; providing molten polymer around the component and between the first surface and the second surface; and hardening the molten polymer and thereby creating the polymer substrate into which the component is integrated based, at least, on cooling the molten polymer.

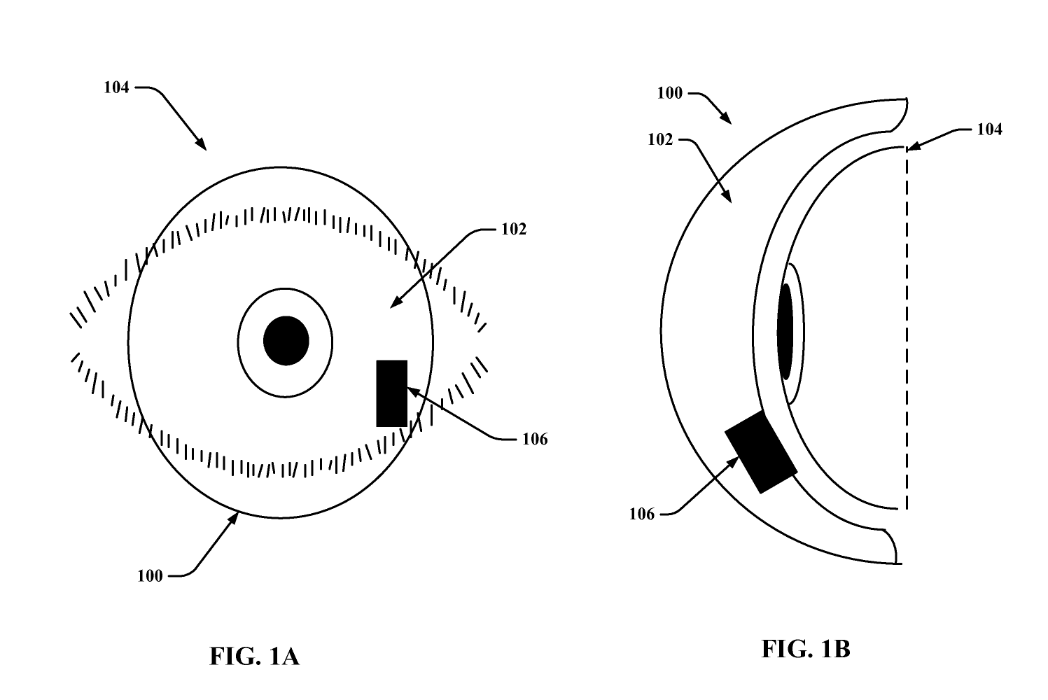

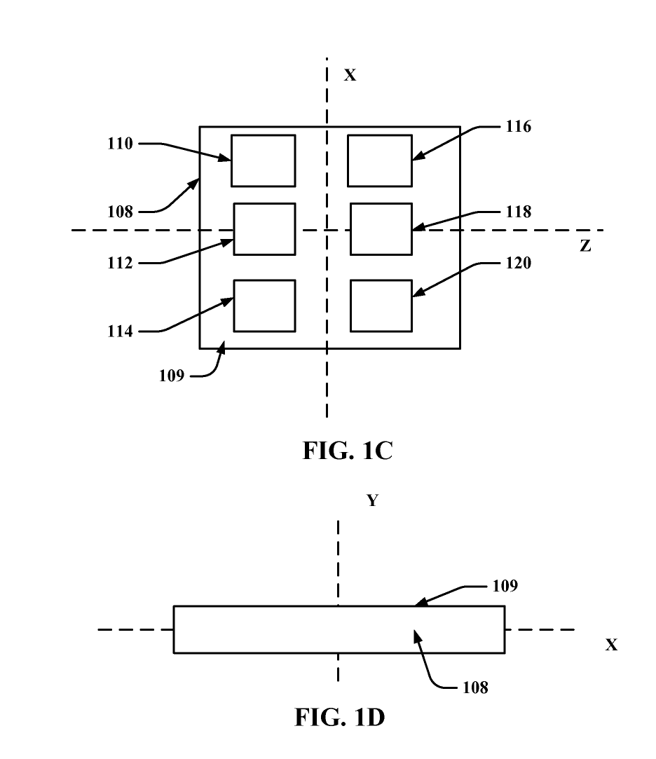

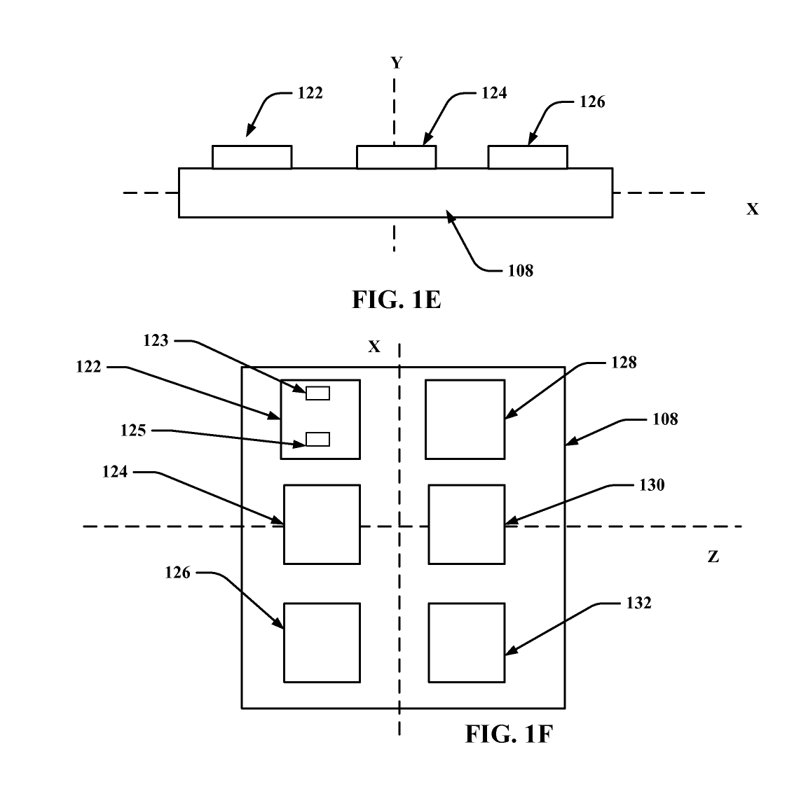

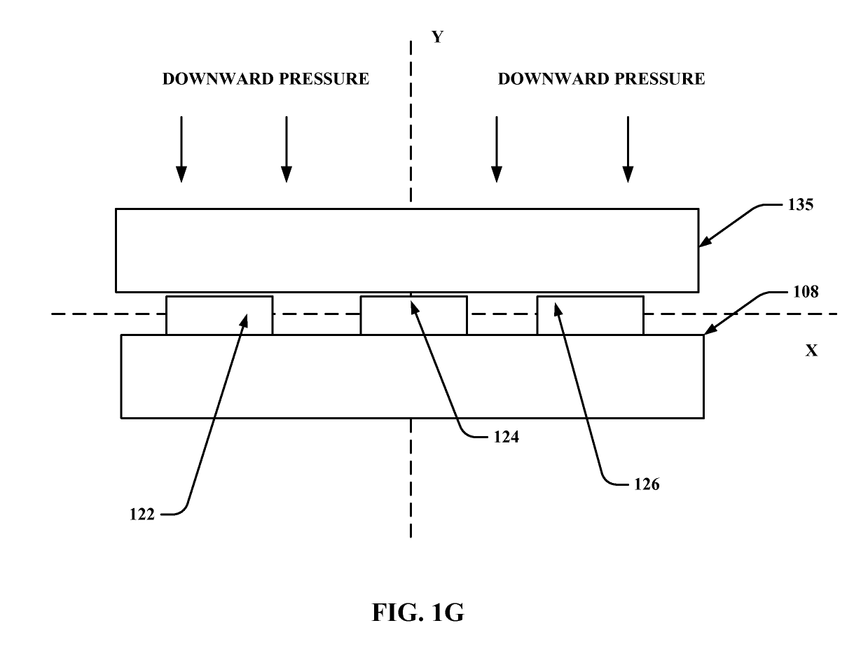

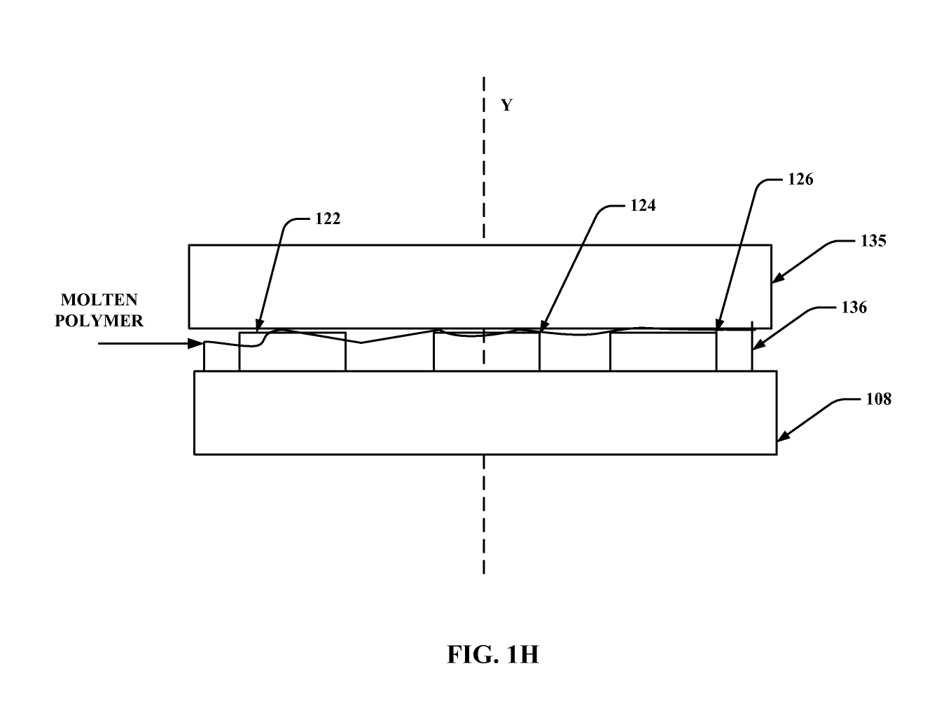

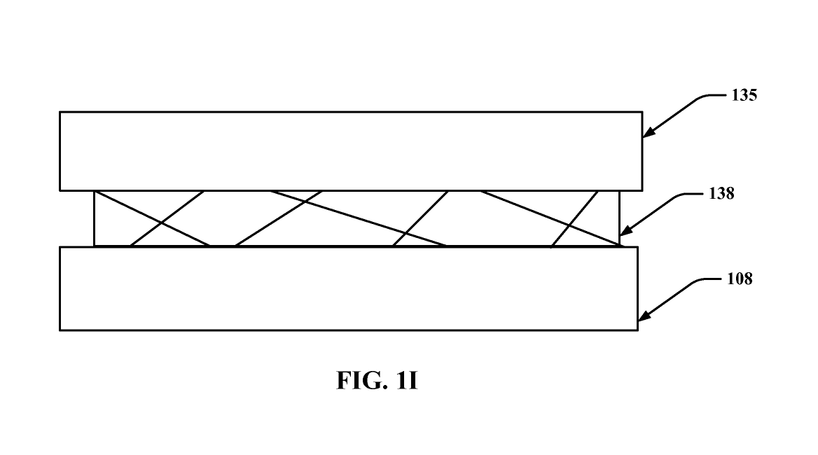

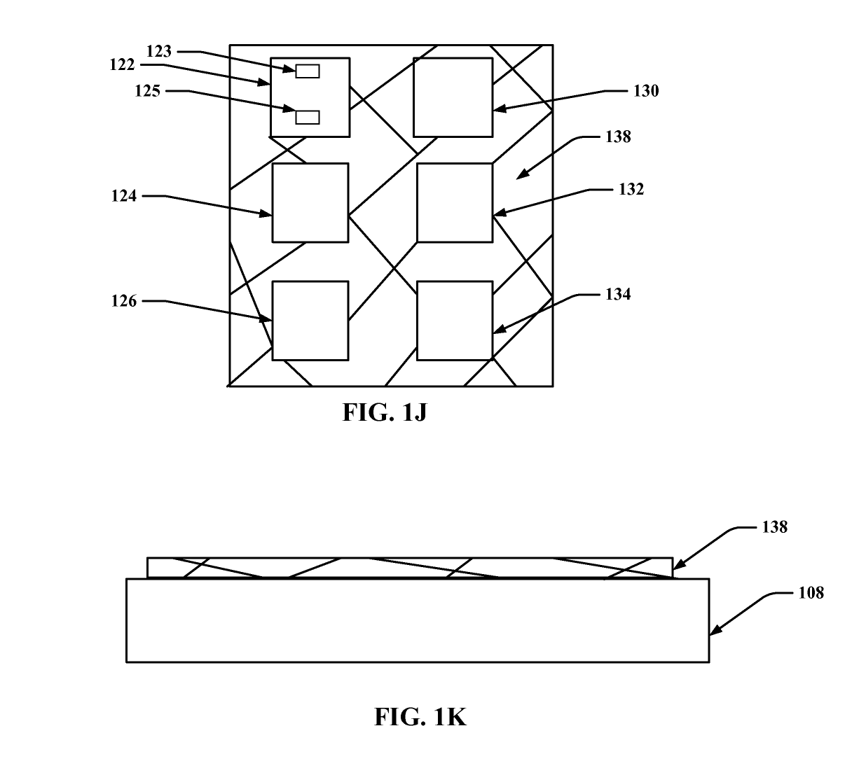

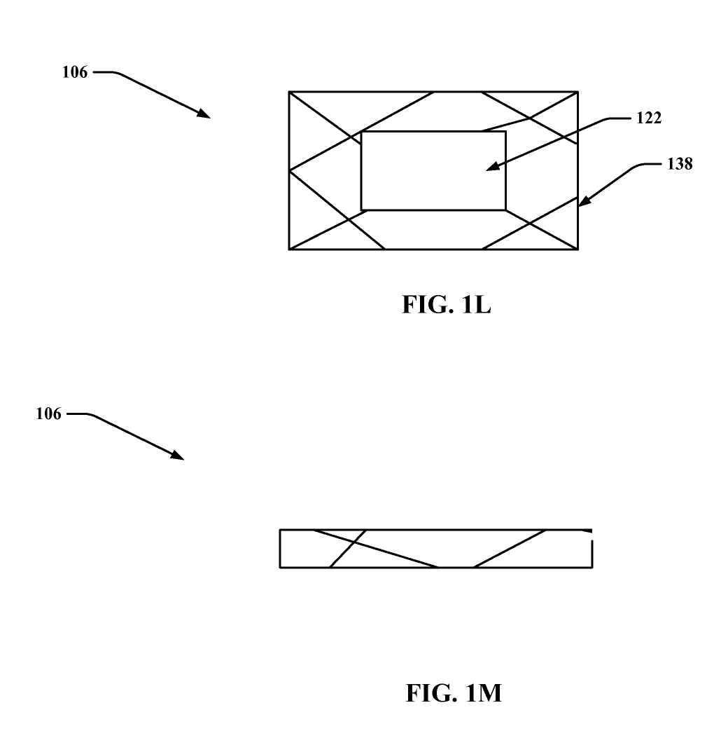

The aspects will now be described in greater detail with reference to the FIGS. 1A-1M. FIGS. 1A and 1B illustrate top and side views of an exemplary non-limiting contact lens having a chip integrated into a polymer substrate in accordance with aspects described herein. Contact lens 100 can include a chip-substrate combination 106 encapsulated in a contact lens polymer 102. The chip-substrate combination 106 can be a chip integrated into a substrate in some aspects. In various aspects, the chip can be configured to facilitate communication between the contact lens 100 and devices external to the contact lens 100 and/or to process information associated with outputs from one or more sensors (not shown) that can be provided on the contact lens 100. As used herein, the term “integrated” can mean the chip is embedded in the substrate such that the chip and substrate surfaces are continuous with no gaps.

While the aspects herein describe and illustrate a chip embedded in a substrate, in other aspects, any suitable other types of components can be embedded in the substrate by substituting the component for the chip. For example, sensors can be embedded in substrates employing the methods described herein.

FIGS. 1C and 1D depict top and side views of a first surface having molds configured to receive and maintain chips in predefined locations. In some aspects, the first surface 108 can be a substantially hard surface composed of silicon wafer, glass or any of a number of different types of metals that are substantially flat and can withstand high temperatures (e.g., steel). The first surface 108 can be substantially flat in some embodiments. In other aspects, the first surface 108 can include a number of indentations and/or molds 110, 112, 114, 116, 118, 120 sized to receive and maintain chips. Accordingly, molds 110, 112, 114, 116, 118, 120 can facilitate positioning the chips in predefined, known locations. As such, concurrent fabrication of a number of chips can be performed.

While the molds 110, 112, 114, 116, 118, 120 are shown in a particular formation relative to one another and having particular shapes, in various aspects, different numbers, shapes and/or formations of molds 110, 112, 114, 116, 118, 120 can be provided in first surface 108. For example, molds 110, 112, 114, 116, 118, 120 can be shaped in any suitable number of shapes corresponding to the shapes of the components to be received and maintained in the mold. As an example, the molds 110, 112, 114, 116, 118, 120 can be rectangular in shape. In other aspects, molds 110, 112, 114, 116, 118, 120 can be triangular, quadrilateral, circular, oval or the like. The molds 110, 112, 114, 116, 118, 120 can be sized to snugly receive and maintain the components provided in the molds 110, 112, 114, 116, 118, 120 in some aspects. Further, different molds having different shapes and/or sizes can be provided together on the first surface 108 to concurrently receive and maintain components of different shapes and sizes.

FIG. 1D is a side view of the first surface 108. As shown, in aspects wherein the first surface 108 includes molds 110, 112, 114, 116, 118, 120 that are indentations in the first surface 108, a side view of the first surface 108 appears substantially flat.

In some aspects, one or more portions of the first surface 108 can be pre-treated with a non-stick coating including, but not limited to, PTFE, TEFLON®, Ecolon, flurosilane or any of a number of different types of silanes. For example, a portion (e.g., top portion 109) of the first surface 108 to which one or more chips and molten polymer will be provided can be coated with a non-stick coating to reduce likelihood of the molten polymer adhering to the first surface 108.

FIGS. 1E and 1F are side and top views of an exemplary non-limiting plurality of chips 122, 124, 126, 128, 130, 132 positioned on a first surface 108 in accordance with aspects described herein. In various aspects, with reference to FIGS. 1C and 1F, the chips 122, 124, 126, 128, 130, 132 can be positioned within the molds 110, 112, 114, 116, 118, 120 to maintain the chips 122, 124, 126, 128, 130, 132 in predefined, known locations for later fabrication.

In various aspects, the chips 122, 124, 126, 128, 130, 132 can include one or more metal pads. The metal pads can be small, thin sheets of metal fabricated on the chips 122, 124, 126, 128, 130, 132 in some aspects. For example, chip 122 can include metal pads 123, 125. The metal pads 123, 125 can be provided on a surface of the chip 122 that is opposite the surface that contacts the first surface 108.

FIG. 1G is a side view of an exemplary non-limiting plurality of chips 122, 124, 126 positioned between a first surface 108 and a second surface 135 in accordance with aspects described herein. As shown, the chips 122, 124, 126 can be disposed between the first surface 108 and the second surface 135. Downward pressure can be applied from the second surface 135 onto the chips 122, 124, 126. In some aspects, the pressure can be applied to lock the chips 122, 124, 126 into place in the molds 110, 112, 114 corresponding to the locations of chips 122, 124, 126.

FIG. 1H is a side view of an exemplary non-limiting plurality of chips 122, 124, 126 positioned between a first surface 108 and a second surface 135 and having molten polymer 136 disposed around the plurality of chips 122, 124, 126 in accordance with aspects described herein. In various aspects, the molten polymer 136 can be flowed between the first surface 108 and second surface 135 and can be provided around a respective perimeter of each of chips 122, 124, 126. While the aspect shown is a side view showing the molten polymer 136 provided around the perimeter of 122, 124, 126, in various aspects, the molten polymer 136 can be provided around the perimeter of any (and all) of the chips 122, 124, 126, 128, 130, 132 on the first surface 108. In various aspects, the molten polymer 136 can be PET, for example.

As shown in FIG. 1H, the molten polymer 136 can fill a substantial entirety of the gap between the first surface 108 and the second surface 135 and create one substrate (e.g., substrate 138 of FIG. 1I) that is substantially the same height (e.g., thickness) as the height of a chip (e.g., chip 122, 124 or 126).

FIG. 1I is an illustration of a side view of an exemplary non-limiting substrate 138 positioned between a first surface 108 and a second surface 135 and having a plurality of chips (not shown) completely embedded in the substrate 138 in accordance with aspects described herein. The molten polymer 136 shown and described with reference to FIG. 1H can be cooled and hardened thereby forming the substrate 138. In various aspects, to form the substrate 138, the molten polymer 136 can be cooled and pressure can be provided on the molten polymer 136 to form the substrate 138.

As shown, the substrate 138 can surround the chips. Because the chips are completely embedded into the substrate 138, in various aspects, as shown, the chips (e.g., chips 122, 124, 126) can be unable to be seen from a side view of the substrate 138. For example, in some aspects, one or more of the sides of the substrate 138 can be a height that is approximately equal to or greater than the height of the chips 122, 124, 126.

In some aspects, the chips 122, 124, 126 can be completely embedded into the substrate 138 with metal pads (not shown) on the chips 122, 124, 126 facing sides of the chips 122, 124, 126 proximate to the second surface 135. For example, although not shown, metal pads 123, 125 described with reference to chip 122 in FIG. 1F can be provided on a surface of chip 122. In some aspects, the metal pads can have a height that is less than or equal to about 10 microns. As such, maximum height of a stack can then be height of the substrate and one or more metal pads on the chip (as compared to cases in which the chip is placed on top of the substrate 138).

In some aspects, then, the metal pads can be substantially level with the surface of the substrate 138. In this aspect, photo resist and pattern metal can be spun directly onto the bond pads (e.g., metal pads) of the chip (e.g., chip 122).

FIG. 1J is a top view of an exemplary non-limiting substrate 138 on the first surface 108 and having chips 122, 124, 126, 128, 130, 132, 134 embedded in the substrate 138 in accordance with aspects described herein. As shown, the second surface (e.g., second surface 135 of FIG. 1I) has been removed and the chips 122, 124, 126, 130, 132, 134 are embedded in the hardened substrate 138 on the first surface 108.

FIG. 1K is a side view of an exemplary non-limiting substrate 138 on the first surface 108 and having chips (not shown) embedded in the substrate 138 in accordance with aspects described herein. The top portions of the chips are not shown in this side view because the chips are completely embedded in the substrate 138 such that the height of the substrate 138 is greater than or equal to the height of the chips.

As described with reference to FIG. 1I, in some aspects, a top portion (or top surface) of a chip can include one or more metal pads (not shown). In FIG. 1K, for example, the height of the substrate can be substantially equal to the combined height of the chip and one or more metal pads on the chip. Accordingly, neither the embedded chip nor the metal pads are viewable in the side view shown in FIG. 1K.

FIG. 1L is an illustration of a top view of a polymer substrate 138 having an integrated chip 122 in accordance with aspects described herein. FIG. 1M is an illustration of a side view of a polymer substrate 138 having an integrated chip (not shown) in accordance with aspects described herein. Specifically, the first surface 108 and the second surface 135 are removed after cooling and hardening the molten polymer 138. Additionally, a chip 122 and portion of the substrate 138 surrounding the chip 122 can be removed from the remaining chips 124, 126, 128, 130, 132 and substrate 138 (before or after further fabrication). The chip 122 and portion of the substrate 138 surrounding the chip 122 can be encapsulated in a contact lens polymer such as contact lens polymer 102 shown and described with reference to FIGS. 1A and 1B.

In some aspects, the combination of the chip 122 and substrate 138 can include the structure and/or functionality of the chip-substrate combination 106 (described with reference to FIGS. 1A and 1B). As shown in FIGS. 1L and 1M, the chip 122 can be integrated into and/or embedded within the substrate 138 such that the surface from the chip to the substrate is continuous with no gaps. The substrate 138 can be provided around the perimeter of the chip 122, for example, as shown.

While FIG. 1L is described as a top view, FIG. 1L can also be the bottom view of the chip-substrate combination 106. For example, the bottom of the chip-substrate combination 106 can include the chip 122 on an inner region of the chip-substrate combination 106 and the substrate 138 along the perimeter of the chip-substrate combination 106. Accordingly, the chip 122 is embedded within the substrate 138 as opposed to being provided on top of the substrate, thereby reducing the thickness of the stack.

Although not shown, in some aspects, metal can be patterned on various locations on the chip-substrate combination 106. The metal can be or include, but is not limited to, a metal line configured to connect the chip 122 with another component, an antenna or a sensor. In other aspects, the metal can be or include an antenna or sensor (or parts thereof).

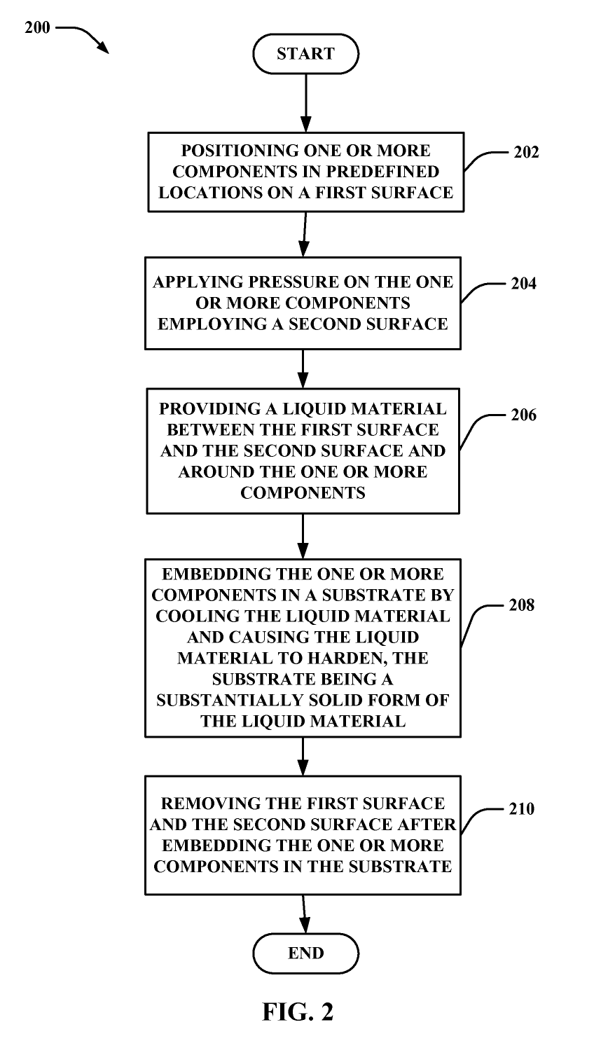

FIGS. 2, 3, 4 and 5 are illustrations of exemplary flow charts of methods of manufacturing a contact lens having a chip integrated into a polymer substrate in accordance with aspects described herein.

Turning first to FIG. 2, at 202, method 200 can include positioning one or more components in predefined locations on a first surface. The components can be chips in some aspects. The chips can be configured to facilitate any number of functions, including, but not limited to, communication from the contact lens or processing of information associated with outputs from one or more sensors on the contact lens. In other aspects, other types of components (e.g., sensors) can be positioned in the predefined locations on the first surface.

In some aspects, the first surface can be a hard surface made of a material such as silicon wafer, glass or any of a number of different types of metals that are substantially flat and can withstand high temperatures (e.g., steel). The first surface can include molds sized to receive the components and maintain the components at the predefined locations. For example, the first surface can be as shown in FIGS. 1C and 1D and include indentations corresponding to the size and shape of the components in order to hold the components in predefined locations.

In various aspects, prior to positioning the components on the first surface, one or more portions of the first surface can be coated with a non-stick coating to reduce the likelihood of the component or molten polymer adhering to the first surface. The non-stick coating can be any suitable number of different types of non-stick coatings that can withstand temperature to which molten polymer can rise (e.g., PTFE, TEFLON®, ceramic-titanium, Ecolon, flurosilane or any of a number of different types of silanes).

At 204, method 200 can include applying pressure on the one or more components employing a second surface. For example, a bottom surface of the components can be provided on the first surface. Next, the second surface can be a hardened surface that can be applied with a downward pressure on the top surface of the components (which is opposite the bottom surface of the components) as shown at FIG. 1G. The pressure can be applied to lock the components in place in the first surface in some aspects. For example, the components can be pressed into the molds in the first surface from the downward pressure applied to the top surface of the components using the second surface. Accordingly, the components can be disposed between the first surface and the second surface. Similar to that for the first surface, in some aspects, one or more portions of the second surface can be coated with a non-stick coating to reduce likelihood of the component or molten polymer adhering to the second surface.

At 206, method 200 can include providing a molten material between the first surface and the second surface and around the one or more components. The molten material can be provided such that the surfaces between the components and the molten material are continuous without gaps between the two surfaces. In various aspects, for example, the molten material can be molten polymer. Molten polymers can include any suitable number of biocompatible polymers including, but not limited to, polyacrylamide, siloxane-based hydrogel and/or fluorosiloxane-based hydrogel.

As shown in FIG. 1H, the molten polymer can be flowed between the first surface and the second surface and around the sides of the components such that the polymer surrounds the sides of the components. In some aspects, each of the components can be surrounded with molten polymer. For example, the chip can be surrounded on n sides when the chip is an n-sided polygon (e.g., the chip can be surrounded on three sides if the chip is triangular in shape while being surrounded on four sides if the chip is rectangular, square or quadrilateral in shape).

At 208, method 200 can include embedding the one or more components in a substrate by cooling the molten material and causing the molten material to harden. As such, the substrate can be a substantially solid form of the molten material. As shown in FIG. 1I, cooling the molten polymer can cause the molten polymer to harden into a solid surface forming a substrate into which the component is embedded. The substrate can have a height that is substantially equal to the height of the chip, and can surround the chip on its sides as shown in FIGS. 1J and 1K.

At 210, method 200 can include removing the first surface and the second surface after embedding the one or more components in the substrate. After removing the first and second surfaces, an array of components embedded into a substrate in predefined locations result. A component and a substrate into which the component is embedded can be cut from the plurality of chips for further fabrication and placement inside of a contact lens. For example, a chip integrated into a substrate can be as shown in FIGS. 1L and 1M.

Although not shown, fabrication can be performed including, but not limited to, patterning metal lines and/or other components on the chip and/or substrate. The metal pads and/or lines can be patterned on the chip, for example, to provide connections between the component embedded in the substrate and another component. Additionally, the component and substrate into which the component is integrated can be provided on or within a contact lens. For example, the component and the substrate can be encapsulated in a contact lens polymer. The contact lens can then be molded with suitable features (e.g., base curve) for the wearer of which the contact lens is designed.

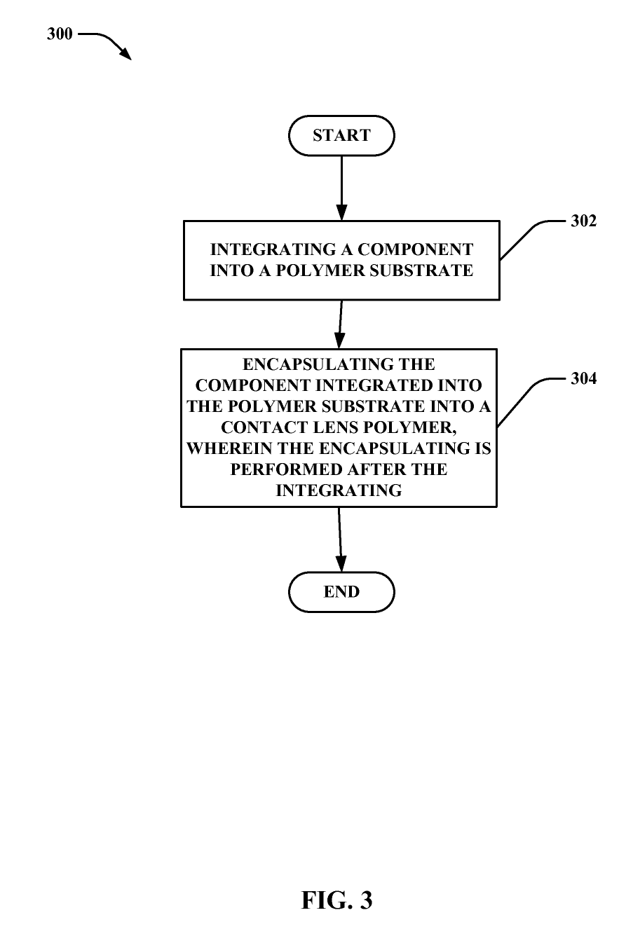

Turning now to FIG. 3, at 302, method 300 can include integrating a component into a polymer substrate. In various aspects, the component can include, but is not limited to, a chip, a sensor or any number of other different types of components typically fabricated on top of a substrate.

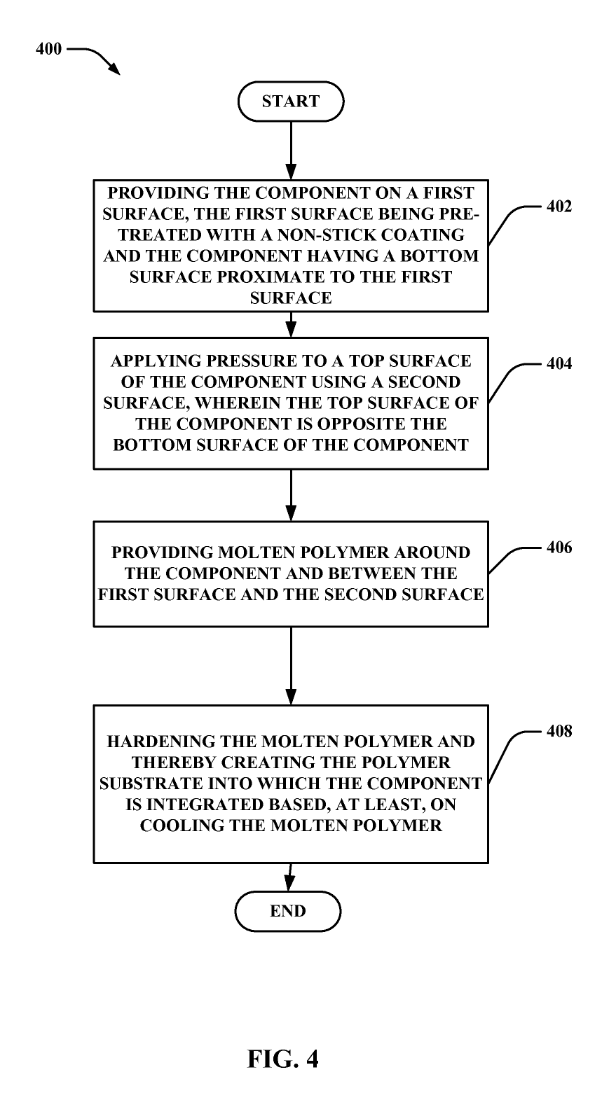

Step 302 of method 300 can be described in greater detail with reference to FIG. 4. Turning to FIG. 4, at 402, method 400 can include providing the component on a first surface, the first surface being pre-treated with a non-stick coating and the component having a bottom surface proximate to the first surface. The non-stick coating can include, but is not limited to, TEFLON®, PTFE or the like. In some aspects, the first surface can be a hard silicon wafer, glass or any of a number of different types of metals that are substantially flat and can withstand high temperatures (e.g., steel). The first surface can be substantially flat with a molded portion sized to snugly receive the component and maintain the component in position at a predefined location.

At 404, method 400 can include applying pressure to a top surface of the component using a second surface, wherein the top surface of the component is opposite the bottom surface of the component. In some aspects, pressure can be applied using a press having a substantially flat surface such that the substantially flat surface of the press contacts the substantially flat surface of the second surface and applies downward pressure fairly evenly over the surface of the component. The pressure can be applied such that the component is locked into and/or resides in the mold of the first surface.

At 406, method 400 can include providing molten polymer around the component and between the first surface and the second surface. In some aspects, the molten polymer can be flowed around the component such that the component is surrounded on various sides by the molten polymer (e.g., surrounded on four sides when the chip is a four-sided polygon, and generally surrounded on n-sides when the chip is an n-sided polygon).

At 408, method 400 can include hardening the molten polymer and thereby creating the polymer substrate into which the component is integrated based, at least, on cooling the molten polymer. In various aspects, the molten polymer can be hardened by compressing the molten polymer.

Turning back to FIG. 3, at 304, method 300 can include encapsulating the component integrated into the polymer substrate into a contact lens polymer, wherein the encapsulating is performed after the integrating. In some aspects, the component and polymer substrate can be provided within liquid contact lens polymer in a contact lens mold. Injection molding can be employed to apply pressure and cool the contact lens polymer to form the contact lens polymer into the shape of a contact lens. The resultant contact lens can then have the polymer substrate (with integrated component) embedded in the contact lens polymer.

While the embodiments described include coating the first surface with a non-stick coating that can withstand temperature to which molten polymer can rise, in some aspects, molten polymer is not employed. Instead, a polymer that does not require high temperatures to become liquefied and that can withstand micro-fabrication processes (e.g., solvents, temperature cycles, ultra-high vacuum) can be employed. For example, some polymers are liquid at room temperature and become a solid after applying heat or after letting the polymer sit for a duration of time (e.g., sitting 48 hours at room temperature). Polydimethylsiloxane (PDMS) and silicone elastomers are examples. PDMS is a liquid at room temperature and can be hardened with either heat or allowing PDMS to sit at room temperature for 48 hours.

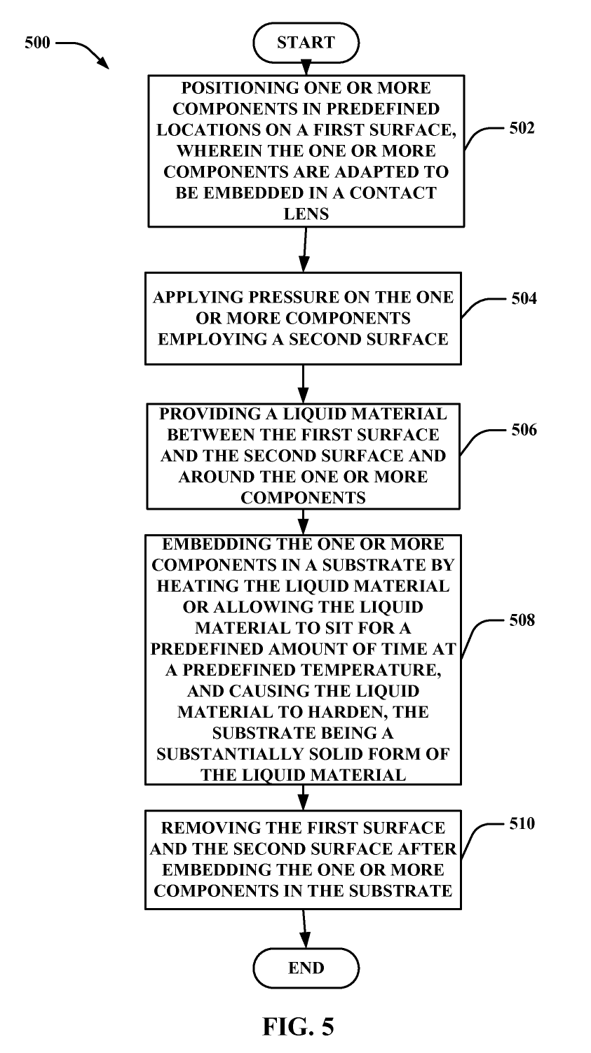

For example, turning to FIG. 5, at 502, method 500 can include positioning one or more components in predefined locations on a first surface, wherein the one or more components are adapted to be embedded in a contact lens. For example, the components can be chips or sensors in various aspects.

At 504, method 500 can include applying pressure on the one or more components employing a second surface. As described with reference to FIGS. 2 and 4, in some aspects, a non-stick coating can be applied to the first surface and/or the second surface. In these aspects, the non-stick coating can be any number of different types of non-stick coatings (e.g., anodized aluminum, PTFE, TEFLON®, ceramic-titanium, Ecolon).

At 506, method 500 can include providing a liquid material between the first surface and the second surface and around the one or more components. In various aspects, the liquid material can be a silicone elastomer or PDMS.

At 508, method 500 can include embedding the one or more components in a substrate by heating the liquid material or allowing the liquid material to sit for a predefined amount of time at a predefined temperature, and causing the liquid material to harden. For example, the liquid material can be allowed to sit for approximately 48 hours at room temperature (e.g., 77 degrees Fahrenheit). The substrate can be a substantially solid form of the liquid material.

At 510, method 500 can include removing the first surface and the second surface after embedding the one or more components in the substrate. A chip and a portion of the substrate into which the chip is embedded can be encapsulated in contact lens polymer.

### Exemplary Networked and Distributed Environments

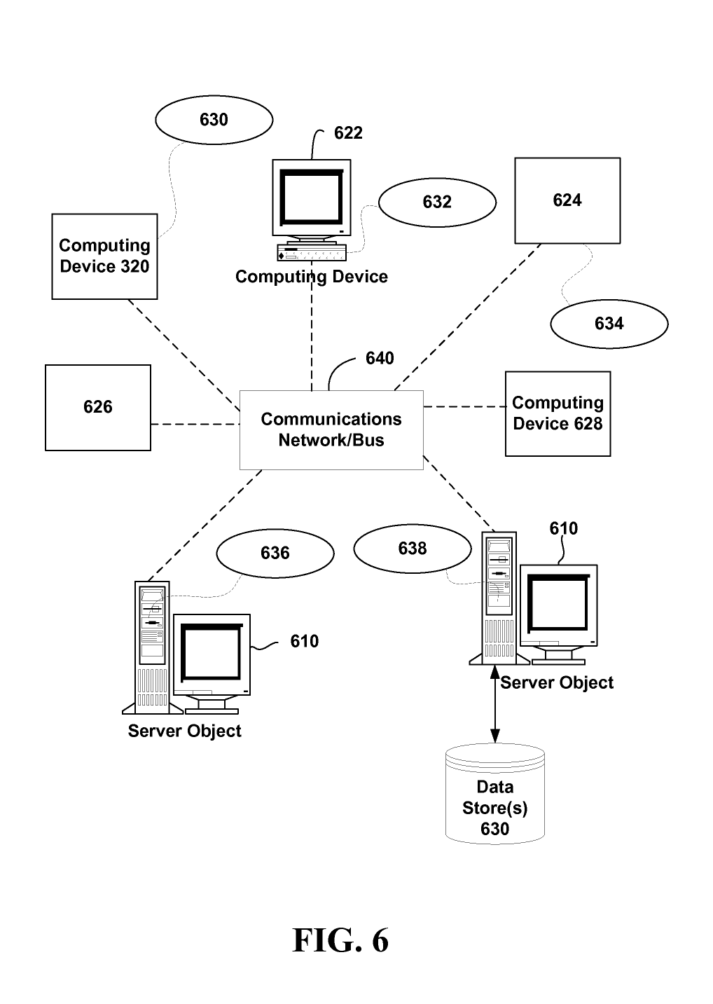

FIG. 6 provides a schematic diagram of an exemplary networked or distributed computing environment with which one or more aspects described in this disclosure can be associated. The distributed computing environment includes computing objects 610, 612, etc. and computing objects or devices 620, 622, 624, 626, 628, etc., which can include programs, methods, data stores, programmable logic, etc., as represented by applications 630, 632, 634, 636, 638. It can be appreciated that computing objects 610, 612, etc. and computing objects or devices 620, 622, 624, 626, 628, etc. can include different devices, such as active contact lenses (and components thereof), personal digital assistants (PDAs), audio/video devices, mobile phones, MPEG-1 Audio Layer 3 (MP3) players, personal computers, laptops, tablets, etc.

Each computing object 610, 612, etc. and computing objects or devices 620, 622, 624, 626, 628, etc. can communicate with one or more other computing objects 610, 612, etc. and computing objects or devices 620, 622, 624, 626, 628, etc. by way of the communications network 640, either directly or indirectly. Even though illustrated as a single element in FIG. 6, network 640 can include other computing objects and computing devices that provide services to the system of FIG. 6, and/or can represent multiple interconnected networks, which are not shown.

In a network environment in which the communications network/bus 640 can be the Internet, the computing objects 610, 612, etc. can be Web servers, file servers, media servers, etc. with which the client computing objects or devices 620, 622, 624, 626, 628, etc. communicate via any of a number of known protocols, such as the hypertext transfer protocol (HTTP).

### Exemplary Computing Device

As mentioned, advantageously, the techniques described in this disclosure can be associated with any suitable device. In various aspects, the data store can include or be included within, any of the memory described herein and/or any of the contact lenses described herein. In various aspects, the data store can be any repository for storing information transmitted to or received from the contact lens.

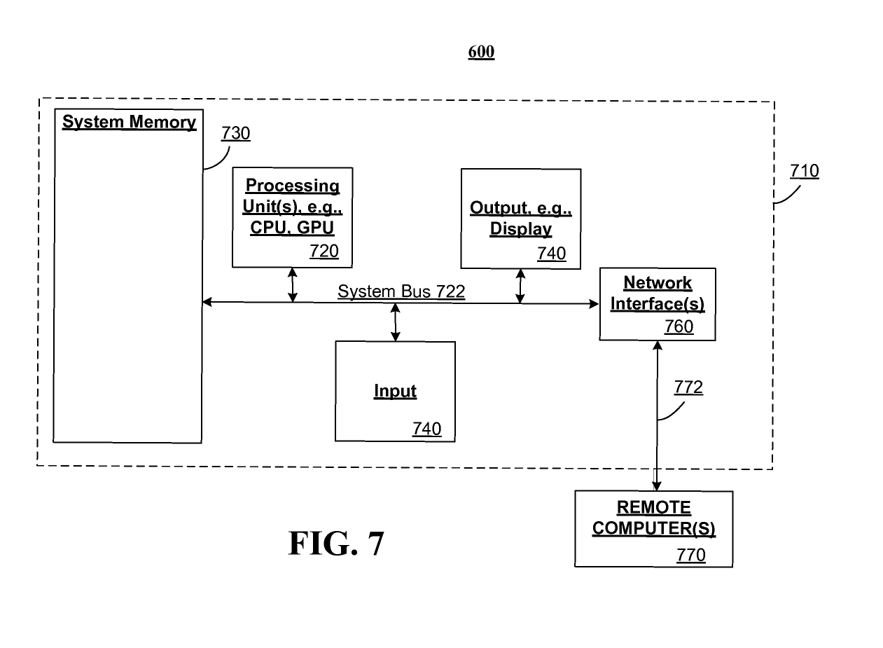

FIG. 7 illustrates an example of a suitable computing system environment 700 in which one or aspects of the aspects described in this disclosure can be implemented. Components of computer 710 can include, but are not limited to, a processing unit 720, a system memory 730, and a system bus 722 that couples various system components including the system memory to the processing unit 720.

Computer 710 typically includes a variety of computer readable media and can be any available media that can be accessed by computer 710. The system memory 730 can include computer storage media in the form of volatile and/or nonvolatile memory such as read only memory (ROM) and/or random access memory (RAM). By way of example, and not limitation, memory 730 can also include an operating system, application programs, other program components, and program data.

A user can enter commands and information into the computer 710 through input devices 740 (e.g., keyboard, keypad, a pointing device, a mouse, stylus, touchpad, touch screen, motion detector, camera, microphone or any other device that allows the user to interact with the computer 710). A monitor or other type of display device can be also connected to the system bus 722 via an interface, such as output interface 750. In addition to a monitor, computers can also include other peripheral output devices such as speakers and a printer, which can be connected through output interface 750.

The computer 710 can operate in a networked or distributed environment using logical connections to one or more other remote computers, such as remote computer 780. The remote computer 780 can be a personal computer, a server, a router, a network PC, a peer device or other common network node, or any other remote media consumption or transmission device, and can include any or all of the elements described above relative to the computer 710. The logical connections depicted in FIG. 7 include a network 782, such local area network (LAN) or a wide area network (WAN), but can also include other networks/buses e.g., cellular networks.

Computing devices typically include a variety of media, which can include computer-readable storage media and/or communications media, in which these two terms are used herein differently from one another as follows. Computer-readable storage media can be any available storage media that can be accessed by the computer, can be typically of a non-transitory nature, and can include both volatile and nonvolatile media, removable and non-removable media. By way of example, and not limitation, computer-readable storage media can be implemented in connection with any method or technology for storage of information such as computer-readable instructions, program components, structured data, or unstructured data. Computer-readable storage media can include, but are not limited to, RAM, ROM, electrically erasable programmable read only memory (EEPROM), flash memory or other memory technology, or other tangible and/or non-transitory media which can be used to store desired information. Computer-readable storage media can be accessed by one or more local or remote computing devices, e.g., via access requests, queries or other data retrieval protocols, for a variety of operations with respect to the information stored by the medium. In various aspects, the computer-readable storage media can be, or be included within, the memory, contact lens (or components thereof) or reader described herein.

On the other hand, communications media typically embody computer-readable instructions, data structures, program components or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals.

It is to be understood that the aspects described in this disclosure can be implemented in hardware, software, firmware, middleware, microcode, or any combination thereof. For a hardware aspect, the processing units can be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors and/or other electronic units designed to perform the functions described in this disclosure, or a combination thereof.

For a software aspect, the techniques described in this disclosure can be implemented with components or components (e.g., procedures, functions, and so on) that perform the functions described in this disclosure. The software codes can be stored in memory units and executed by processors.

What has been described above includes examples of one or more aspects. It is, of course, not possible to describe every conceivable combination of components or methodologies for purposes of describing the aforementioned aspects, but one of ordinary skill in the art can recognize that many further combinations and permutations of various aspects are possible. Accordingly, the described aspects are intended to embrace all such alterations, modifications and variations that fall within the spirit and scope of the appended claims.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The aforementioned systems have been described with respect to interaction between several components. It can be appreciated that such systems and components can include those components or specified sub-components. Sub-components can also be implemented as components communicatively coupled to other components rather than included within parent components (hierarchical). Additionally, it is to be noted that one or more components can be combined into a single component providing aggregate functionality. Any components described in this disclosure can also interact with one or more other components not specifically described in this disclosure but generally known by those of skill in the art.

In view of the exemplary systems described above methodologies that can be implemented in accordance with the described subject matter will be better appreciated with reference to the flowcharts of the various figures. While for purposes of simplicity of explanation, the methodologies are shown and described as a series of blocks, it is to be understood and appreciated that the claimed subject matter is not limited by the order of the blocks, as some blocks can occur in different orders and/or concurrently with other blocks from what is depicted and described in this disclosure. Where non-sequential, or branched, flow is illustrated via flowchart, it can be appreciated that various other branches, flow paths, and orders of the blocks, can be implemented which achieve the same or a similar result. Moreover, not all illustrated blocks may be required to implement the methodologies described in this disclosure after.

In addition to the various aspects described in this disclosure, it is to be understood that other similar aspects can be used or modifications and additions can be made to the described aspect(s) for performing the same or equivalent function of the corresponding aspect(s) without deviating there from. Still further, multiple processing chips or multiple devices can share the performance of one or more functions described in this disclosure, and similarly, storage can be provided across a plurality of devices. The invention is not to be limited to any single aspect, but rather can be construed in breadth, spirit and scope in accordance with the appended claims.

What is claimed is:

1. A method, comprising:
positioning one or more components in predefined locations on a first surface, wherein the one or more components are adapted to be embedded in a contact lens;
applying pressure on the one or more components employing a second surface;
providing a molten material between the first surface and the second surface and around the one or more components;
embedding the one or more components in a substrate by cooling the molten material and causing the molten material to harden, the substrate being a substantially solid form of the molten material; and
removing the first surface and the second surface after embedding the one or more components in the substrate.

2. The method of claim 1, further comprising:
encapsulating, in the contact lens, at least one of the one or more components and a portion of the substrate, wherein the at least one of the one or more components is embedded into the portion of the substrate.

3. The method of claim 1, wherein the first surface comprises respective one or more molds sized to receive the one or more components and maintain the one or more components at the predefined locations.

4. The method of claim 1, further comprising:
pre-treating at least one of the first surface or the second surface with a non-stick coating.

5. The method of claim 4, wherein the non-stick coating comprises at least one of Polytetrafluoroethylene, flurosilane or a silane material.

6. The method of claim 4, wherein the pre-treating is performed prior to the positioning of the one or more components in the predefined locations on the first surface.

7. The method of claim 1, wherein the providing the molten material between the first surface and the second surface and around the one or more components comprises providing the molten material such that a surface of the one or more components and a surface of the molten material are continuous.

8. The method of claim 1, wherein the first surface is comprised of at least one of a silicon wafer, glass or metal.

9. The method of claim 1, wherein the one or more components comprise one or more chips.

10. The method of claim 9, wherein the one or more chips are configured to facilitate at least one of communication from the contact lens or processing information associated with outputs from one or more sensors on the contact lens.

11. The method of claim 1, wherein the molten material comprises a polymer.

12. The method of claim 11, wherein the polymer comprises polyethylene terephthalate.

13. The method of claim 1, further comprising:
patterning metal on at least one of the one or more components or the substrate.

14. The method of claim 13, wherein the metal comprises at least one of: a metal line configured to connect the one or more components with another component, an antenna or a sensor.

15. A contact lens, comprising:
a chip embedded in a substrate such that the chip and the substrate form a continuous surface, wherein the chip is embedded in the substrate based, at least, on a hardening of molten liquid provided around the chip; and
a contact lens polymer encapsulating the chip and the substrate.

16. The contact lens of claim 15, wherein the molten material comprises polyethylene terephthalate.

17. The contact lens of claim 15, further comprising:
metal patterned on the substrate, wherein the metal comprises at least one of: a metal line configured to connect the chip with a component on the contact lens, a sensor or an antenna.

18. A method, comprising:
integrating a component into a polymer substrate, wherein the integrating comprises:
providing the component on a first surface, the first surface being pre-treated with a non-stick coating and the component having a bottom surface positioned on the first surface;
applying pressure to a top surface of the component using a second surface, wherein the top surface of the component is opposite the bottom surface of the component;
providing molten polymer around the component and between the first surface and the second surface; and
hardening the molten polymer and thereby creating the polymer substrate into which the component is integrated based, at least, on cooling the molten polymer.

19. The method of claim 18, further comprising:
encapsulating the component and the polymer substrate in a contact lens polymer, wherein the encapsulating is performed after the integrating.

20. The method of claim 18, wherein the component comprises at least one of a chip or a sensor.

21. A method, comprising:
positioning one or more components in predefined locations on a first surface, wherein the one or more components are adapted to be embedded in a contact lens;
applying pressure on the one or more components employing a second surface;
providing a liquid material between the first surface and the second surface and around the one or more components;
embedding the one or more components in a substrate by at least one of heating the liquid material or allowing the liquid material to sit for a predefined amount of time at a predefined temperature, and causing the liquid material to harden, the substrate being a substantially solid form of the liquid material; and
removing the first surface and the second surface after embedding the one or more components in the substrate.

22. The method of claim 21, wherein the liquid material comprises at least one of a silicone elastomer or polydimethylsiloxane.
